(19) United States
(12) Patent Application Publication
(10) Pub. No.: US 2018/0158995 A1
(43) Pub. Date: Jun. 7, 2018

(54) WAVELENGTH COINVENTOR, FLUORESCENT COLOR WHEEL, AND LIGHT-EMITTING DEVICE

(71) Applicant: APPOTRONICS CORPORATION LIMITED, Shenzhen (CN)

(72) Inventors: Qian LI, Shenzhen (CN); Yusan CHEN, Shenzhen (CN); Yangang WANG, Shenzhen (CN); Yanzheng XU, Shenzhen (CN)

(21) Appl. No.: 15/570,441

(22) PCT Filed: Apr. 29, 2016
(86) PCT No.: PCT/CN2016/080643

§ 371 Date: Oct. 30, 2017

(30) Foreign Application Priority Data
Apr. 29, 2015 (CN) 201510210137.4

(51) Int. Cl. H01L 33/50; H01L 33/46; G02B 26/00; G02F 1/23

(52) U.S. Cl. CPC H01L 33/504; G02F 1/23; G02B 26/008; H01L 33/46

(57) ABSTRACT

A wavelength converter is provided. The wavelength converter comprises a light emitting-reflecting layer, and the light emitting-reflecting layer comprises a wavelength converting material, aluminum oxide, titanium oxide and an adhesive, which not only reduces the heat generated by the light propagation in the light emitting-reflecting layer, but also improves the density and heat dissipation performance of the wavelength converter. Thus, the wavelength converter is more applicable to a high-power excitation light source. A fluorescent color wheel and a light-emitting device comprising the wavelength converter are also provided.

### FIELD OF THE DISCLOSURE

The present disclosure relates to the technical field of wavelength converting and light emitting, and more specifically, relates to a wavelength converter, a fluorescent color wheel, and a light-emitting device for a high-power laser light source.

### BACKGROUND

In the current lighting and projection field, as the demand for brightness gradually increases in production and daily life, light bulbs directly emitting white light are unable to meet the needs of light when adopted as light sources. Solid-state light sources, such as light-emitting diodes (LEDs) and laser diodes (LDs), play an increasingly important role in the field of high-brightness and high-power lighting.

However, LEDs and LDs cannot provide white light directly and, thus, when LEDs or LDs are used as the light-emitting element of the light source, white light is often obtained by mixing light of three primary colors, i.e. red, green and blue primary light. In particular, in the application of exciting a fluorescent color wheel by an excitation light, a multi-stage color wheel is often adopted to obtain the respective primary color lights, then white light is obtained by mixing the primary color lights in a time sequence. Such a method of obtaining white light has a low efficiency and, meanwhile, is not favorable for individually modulating the white light.

On the other hand, white LED lighting is often realized by combining a blue LED and YAG phosphor, in which the blue LED excites the YAG phosphor to generate yellow light, then yellow light and blue light are mixed together to get white light. However, in the existing white LED lighting, the YAG phosphor is often coated with a transparent medium and made as a layer (i.e., a YAG phosphor layer). The blue light is partially absorbed when passing through the transparent medium, which increases the temperature of the transparent medium and the YAG phosphor, and decreases the luminous efficiency of the phosphor. Such problems become more and more severe as the power of the excitation light increases gradually.

### BRIEF SUMMARY OF THE DISCLOSURE

In view of the above-mentioned heating problem in the YAG phosphor layer in the existing technologies, the present disclosure provides a wavelength converter for a light source of high-power laser, which may absorb less excitation light, generate less heat, and have an improved reliability.

The present disclosure provides a wavelength converter comprising a light emitting-reflecting layer. The light emitting-reflecting layer comprises a wavelength converting material, aluminum oxide, titanium oxide and an adhesive.

The present disclosure also provides a fluorescent color wheel comprising the wavelength converter, and the light emitting-reflecting layer of the wavelength converter has a ring shape or an annual sector shape.

The present disclosure also provides a light-emitting device comprising the wavelength converter, and further comprising an excitation light source. The excitation light source is a solid-state light source.

Compared with the prior art, the present disclosure provides the following advantageous.

Through configuring a light emitting-reflecting layer comprising a wavelength converting material, aluminum oxide, titanium oxide and an adhesive, the wavelength converting material and the reflective material are disposed in the same layer. Thus, when the excitation light is incident onto the light emitting-reflecting layer, partial of the excitation light may be directly reflected by the light emitting-reflecting layer, reducing the medium's temperature increase caused by the propagation of the excitation light in the light emitting-reflecting layer. Meanwhile, aluminum oxide and titanium oxide may provide a substantially higher reflectivity with a substantially smaller content, and fill the space among large particles in the wavelength converting material, which may improve the density and thermal conductivity of the light-emitting layer, reduce the heat generated in the wavelength converter, and enhance the heat dissipation performance of the wavelength converter. The disclosed wavelength converter may be applicable to a excitation light source with a substantially high power.

### BRIEF DESCRIPTION OF THE DRAWINGS

FIG. 1 illustrates a schematic diagram of an exemplary wavelength converter according to a first embodiment;

FIG. 2 illustrates a schematic diagram of an exemplary wavelength converter according to a second embodiment;

FIG. 3 illustrates a schematic diagram of an exemplary wavelength converter according to a third embodiment; and

FIG. 4 illustrates a schematic diagram of an exemplary fluorescent color wheel according to a fourth embodiment.

### DETAILED DESCRIPTION

### First Embodiment

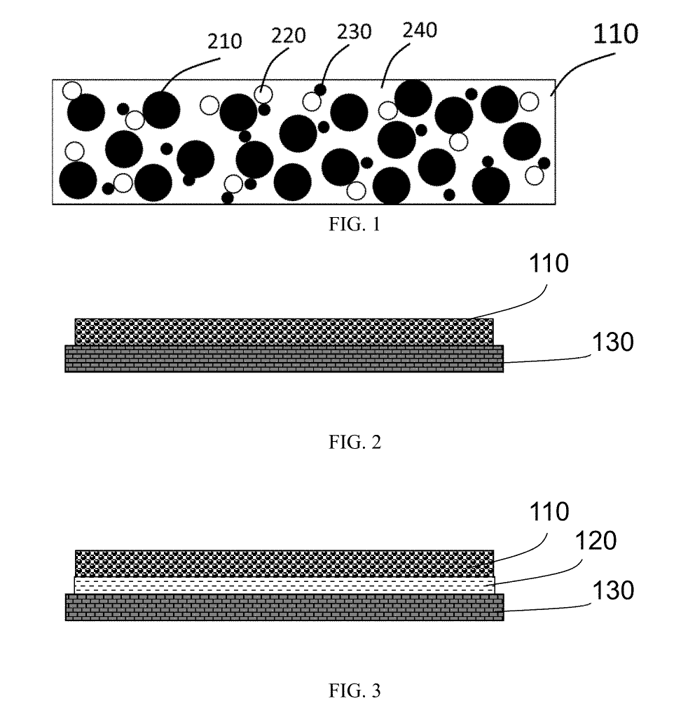

FIG. 1 illustrates a schematic diagram of an exemplary wavelength converter according to a first embodiment. As shown in FIG. 1, the wavelength converter may comprise a light emitting-reflecting layer 110. The light emitting-reflecting layer 110 may comprise a wavelength converting material 210, titanium oxide particles 220, aluminum oxide particles 230, and an adhesive 240. The light emitting-reflecting layer 110 may reflect the incident light and, meanwhile, emit an excited light after being excited.

In particular, the wavelength converting material may convert an excitation light from an excitation light source into an exited light. The wavelength converting material 210 may be disposed in the light emitting-reflecting layer 110, and form light emission centers and heating centers. The titanium oxide particles 220 and the aluminum oxide particles 230 may be disposed in spaces among the particles in the wavelength converting material 210, reflecting incident light. The titanium oxide particles 220 may have a substantially high reflectance for light having a wavelength above 550 nm but a substantially low reflectivity for short-wavelength visible light, while the aluminum oxide particles 230 may have a substantially high reflectance for blue light, and more specifically, light having a wavelength below 480 nm. For light having a broad spectrum, and more specifically, white light, using a single type of reflective particles (i.e., aluminum oxide particles or titanium oxide particles alone) may not achieve the desired reflectance. Thus, the present disclosure provides a combination of aluminum oxide particles 230 and titanium oxide particles 220. In addition, the inventors have found that after the aluminum oxide particles and titanium oxide particles are mixed, the mixed reflective particles are easy to form a film and fill the spaces among the particles, such that the film of mixed reflective particles can achieve a higher reflectivity in a smaller content. The adhesive 240 may bond the wavelength converting material 210, the titanium oxide particles 220, and the aluminum oxide particles 230 into the film.

In the disclosed embodiments, the wavelength converting material 210 may include YAG: Ce phosphor having a substantially high luminous efficiency, and a larger particle size (i.e., diameter of the particle) than the titanium oxide particles 220 and the aluminum oxide particles 230. On one hand, YAG: Ce phosphors may have a high luminous efficiency, on the other hand, the titanium oxide particles and the aluminum oxide particles of a smaller particle size may be filled into the spaces among the large particles of YAG: Ce phosphor, such that the light emitting-reflecting layer may be more dense. In another embodiment, the wavelength converting material may also include a combination of two or more phosphors such as a mixture of green phosphors and red phosphors. When illuminated by blue light, the light emitting-reflecting layer may emit red, green and blue primary light, and the white balance may be adjusted by controlling the content of green phosphor and red phosphor.

The particle size of the phosphor may be in a range of 1 to 50 μm. Optionally, the particle size of the phosphor may be in a range of 10 to 20 μm. The phosphor having a smaller particle size may have a lower luminous intensity, while the phosphor having a larger particle size may be not easy to be formed.

Aluminum oxide and titanium oxide may have a particle size in the range of 0.05 to 5 μm. Optionally, the particle size of the aluminum oxide and titanium oxide may have a particle size in the range of 0.1 to 1 μm. When the particle size of the aluminum oxide and titanium oxide is too small, the adhesive may be likely to have a porous structure, degrading the thermal conductivity of the light emitting-reflecting layer. When the particle size of the aluminum oxide and titanium oxide is too large, the aluminum oxide and titanium oxide may be unable to fill into the spaces among the phosphors, which may increase the thickness of the light emitting-reflecting layer.

In the disclosed embodiments, the wavelength converting material 210 may account for 20%˜60% of the mass of the light emitting-reflecting layer 110, the titanium oxide particles 220 may account for 0.1%˜5% of the mass of the light emitting-reflecting layer 110, and the aluminum oxide particles 230 may account for 0.1%˜5% of the mass of the light emitting-reflecting layer 110. The titanium oxide particles and the aluminum oxide particles have a substantially small particle size, which may tend to generate spaces among the particles when the adhesive is coated on the particles. Thus, the content of the titanium oxide particles and the aluminum oxide particles in the light emitting-reflecting layer 110 may not be excessive. Meanwhile, to ensure the most sufficient reflectivity, the content of the titanium oxide particles and the aluminum oxide particles in the light emitting-reflecting layer 110 may also have to be sufficient.

Optionally, the wavelength converting material (phosphors) 210 may account for 35%˜55% of the mass of the light emitting-reflecting layer 110, the titanium oxide particles 220 may account for 0.1%˜1% of the mass of the light emitting-reflecting layer 110, and the aluminum oxide particles 230 may account for 0.1%˜1% of the mass of the light emitting-reflecting layer 110.

In the disclosed embodiments, the adhesive 240 may be continuously distributed, i.e. any point in the adhesive 240 in the light emitting-reflecting layer 110 may reach another point in the adhesive 240 without crossing any interface, or only the adhesive 240 in some areas may have to cross an interface to reach the adhesive 240 in some other areas. The continuously distributed structure of the adhesive 240 may have good thermal and compressive properties, and heat may not have to pass through the interface when being transmitted inside the continuously distributed structure, which may reduce the interface thermal resistance. To achieve the continuously distributed structure of the adhesive 240, the content of the adhesive may have to be sufficient and, meanwhile, to ensure that the utilization of the wavelength converting material 210, the content of the adhesive may not be excessive. In the disclosed embodiments, the mass percentage of the adhesive may be 40%˜80%, and optionally, the mass percentage of the adhesive may be 45%˜65%.

In the disclosed embodiments, the adhesive may be a glass medium, which may be continuously distributed. To ensure the light transmission, thermal conductivity and temperature resistance, the glass medium may include one or more of SiO₂—B₂O₃—RO, SiO₂—TiO₂—Nb₂O₅—R′₂O, and ZnO—P₂O₅, in which R may include one or more of Mg, Ca, Sr, Ba, Na, and K, and R may include one or more of Li, Na, and K.

In certain embodiments, the adhesive may also be silica gel or silicone resin, which may be applicable for a lower power excitation light source.

### Second Embodiment

FIG. 2 illustrates a schematic diagram of an exemplary wavelength converter according to a second embodiment. As show in FIG. 2, the wavelength converter may comprise a light emitting-reflecting layer 110 and a substrate 130.

The light emitting-reflecting layer 110 may refer to the light emitting-reflecting layer in the First Embodiment. The substrate 130 may be an aluminum nitride ceramic substrate, which may have a high thermal conductivity and a good bonding performance with the light emitting-reflecting layer 110 comprising the aluminum oxide and titanium oxide.

In another embodiment, the substrate 130 may be another ceramic substrate, such as an aluminum oxide substrate, a boron nitride substrate, a silicon nitride substrate, a silicon carbide substrate, or a beryllium oxide substrate.

In another embodiment, the substrate 130 may be a metal substrate, such as an aluminum substrate or a copper substrate, which has a better thermal conductivity. When the adhesive in the light emitting-reflecting layer 110 is a glass medium, a metal layer or a solder layer may be disposed between the metal substrate and the light emitting-reflecting layer, enhancing the bonding between the metal substrate and the light emitting-reflecting layer. When the adhesive is silica gel or silicone resin, the metal layer may be neglected.

In another embodiment, the substrate 130 may be a metal-ceramic alloy substrate, such as an aluminum-aluminum nitride alloy substrate, which may have both a high thermal conductivity of the aluminum metal and a low coefficient of thermal expansion of the aluminum nitride, and may be easily boned to the light emitting-reflecting layer.

### Third Embodiment

FIG. 3 illustrates a schematic diagram of an exemplary wavelength converter according to a third embodiment. As shown in FIG. 3, the wavelength converter may comprise a light emitting-reflecting layer 110, a pure reflective layer 120, and a substrate 130. Compared to the wavelength converter according to the Second Embodiment, in the wavelength converter according to the Third Embodiment, the pure reflective layer 120 may be introduced between the light emitting-reflecting layer 110 and the substrate 130, in which the pure reflective layer 120 may reflect the light transmitted through the light emitting-reflecting layer 110.

The pure reflective layer 120 may comprise aluminum oxide, titanium oxide and an adhesive, in which the adhesive may be the same as the adhesive in the light emitting-reflecting layer, such that the pure reflective layer 120 and the light emitting-reflecting layer 110 may be tightly bonded without being peeled off due to an external force or temperature change.

Aluminum oxide has excellent visible light reflectivity. The visible light reflectivity of a pure aluminum oxide layer may reach 90%. However, due to large spaces among the aluminum oxide particles, the light may bypass the aluminum oxide particles and become transmitted. As a result, the aluminum oxide layer may desire a substantially large thickness to achieve the above-mentioned reflectivity (i.e., 90%). However, when the thickness of the aluminum oxide layer increases, the thermal conductivity of the aluminum oxide layer may be degraded. Titanium oxide itself has a certain reflectivity, and more specifically, has a better reflectivity for light having a wavelength above 550 nm. However, the titanium oxide has a poor reflectivity for light having a wavelength below 480 nm, which may not meet the performance requirements of a reflective layer. After mixing the aluminum oxide and titanium oxide, the reflective layer of mixed aluminum oxide and titanium oxide is found to easily form a film, and the titanium oxide fills the spaces among the aluminum oxide particles and utilizes the own reflection characteristics to ensure that the light transmitted through the spaces among the aluminum oxide particles is going to be reflected. Thus, the reflective layer of mixed aluminum oxide and titanium oxide may achieve a higher reflectivity at a smaller thickness. In addition, compared to the aluminum oxide, the titanium oxide may have a better wettability with a softened adhesive (e.g., glass powder, silica gel or silicone resin), such that closed bubbles may be suppressed to be formed inside the adhesive.

In the disclosed embodiments, to enhance the reflectivity, the aluminum oxide particles may account for 1%˜60% of the mass of the pure reflective layer 120, the titanium oxide particles may account for 1%˜40% of the mass of the pure reflective layer 120, and the adhesive may account for 30%˜70% of the mass of the pure reflective layer 120.

In the disclosed embodiments, the light emitting-reflecting layer 110 and the pure reflective layer 120 may be bonded together by the same sintering process. Before sintering, dried slurry of the light emitting-reflecting layer 110 and the pure reflective layer 120 may be stacked in layers, which may be later subjected to the same sintering process to form the light emitting-reflecting layer 110 and the pure reflective layer 120, respectively, ensuring the overall uniformity of the wavelength converter.

### Fourth Embodiment

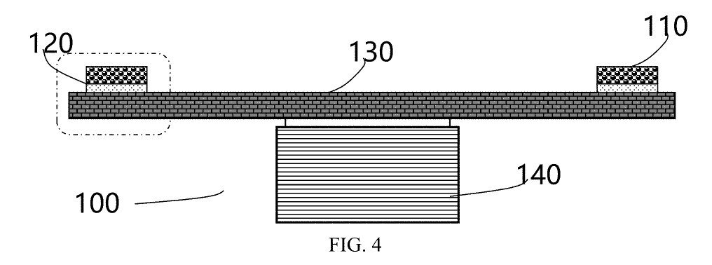

FIG. 4 illustrates a schematic diagram of an exemplary fluorescent color wheel according to a fourth embodiment. As shown in FIG. 4, the fluorescent color wheel 100 may comprise a light emitting-reflecting layer 110, a pure reflective layer 120, a substrate 130, and a driving device 140. The arrangement of the light emitting-reflecting layer 110, the pure reflective layer 120, and the substrate 130 may refer to the above-described embodiments. The driving device 140 may drive the substrate around the central axis of the substrate.

In the disclosed embodiments, the substrate 130 may have a circular shape, and the light emitting-reflecting layer 110 and the pure reflective layer 120 may both have a ring shape. In certain embodiments, the light emitting-reflecting layer 110 may also be formed by splicing a plurality of annular sectors together. As discussed in the First Embodiment, the pure reflective layer 120 may be neglected, and the light emitting-reflecting layer 110 may be directly bonded to the substrate 130 when light cannot be transmitted through the light emitting-reflecting layer 110.

### Fifth Embodiment

The Fifth Embodiment is modified on the basis of the Fourth embodiment. In the disclosed embodiment, the fluorescent color wheel may be a multi-stage color wheel. When the excitation light is irradiated onto the light-emitting surface of the rotating color wheel as a light spot, the color wheel emits light of different wavelengths in a time sequence. The light-emitting layer of the color wheel may comprise a light emitting-reflecting layer emitting white light as described in the First Embodiment, and the light-emitting layer of the color wheel may further include light-emitting segments formed by phosphors and an adhesive (excluding titanium oxide and aluminum oxide) and capable of emitting light in other colors. For example, the light-emitting layer of the color wheel may include the light emitting-reflective layer which emits white light, a green phosphor layer, a red phosphor layer and a transparent diffusion layer, such that the color wheel may emit red, green, blue and white light given a blue excitation light source, which may greatly enhance the luminous brightness and improve the luminous efficiency. In certain embodiments, the light-emitting layer of the color wheel may include the light emitting-reflective layer emitting white light, and other light-emitting segments emitting light in a spectral range narrower than white light, which may be a simple alternative to the above-mentioned fluorescent color wheel emitting red, green, green and white light.

The present disclosure also provides a light-emitting device, which may use the wavelength converter in the disclosed embodiments as a light-emitting module and further include an excitation light source. The execution light source may be a solid light source, such as an LD or an LED, and the excitation light source may excite the wavelength converter to emit excited light.

Various embodiments of the present specification are described in a progressive manner, in which each embodiment focusing on aspects different from other embodiments, and the same and similar parts of each embodiment may be referred to each other.

The present disclosure may be implemented and used according to above description of embodiments of the present disclosure by the skilled person in the art. It is apparent that various modifications of the embodiments may be made by the person skilled in the art. The general principle defined herein may be applicable in other embodiments without departing from the spirit and scope of the present disclosure. Therefore, the present disclosure will not be limited to the embodiments of the present disclosure and confirms to a widest scope in accordance with the disclosed principle and the novelty features of the present disclosure.

1. A wavelength converter, comprising:
a light emitting-reflecting layer,
wherein the light emitting-reflecting layer comprises a wavelength converting material, aluminum oxide, titanium oxide and an adhesive.

2. The wavelength converter according to claim 1, wherein:
the wavelength converting material includes a phosphor;
a particle size of the phosphor is larger than a particle size of the titanium oxide and a particle size of the aluminum oxide; and
the phosphor is a YAG:Ce phosphor or a mixture of a green phosphor and a red phosphor.

3. The wavelength converter according to claim 2, wherein:
the particle size of the phosphor is a range of 1 to 50 μm;
the particle size of the aluminum oxide is in a range of 0.05 to 5 μm;
the particle size of the titanium oxide is in a range of 0.05 to 5 μm.

4. The wavelength converter according to claim 3, wherein:
the particle size of the phosphor is a range of 10 to 20 μm;
the particle size of the aluminum oxide is in a range of 0.1 to 1 μm;
the particle size of the titanium oxide is in a range of 0.1 to 1 μm.

5. The wavelength converter according to claim 1, wherein:
the wavelength converting material accounts for 20%˜60% of a mass of the light emitting-reflecting layer;
the titanium oxide accounts for 0.1%˜5% of the mass of the light emitting-reflecting layer; and
and the aluminum oxide accounts for 0.1%˜5% of the mass of the light emitting-reflecting layer.

6. The wavelength converter according to claim 5, wherein:
the wavelength converting material accounts for 35%˜55% of the mass of the light emitting-reflecting layer;
the titanium oxide accounts for 0.1%˜1% of the mass of the light emitting-reflecting layer; and
the aluminum oxide accounts for 0.1%˜1% of the mass of the light emitting-reflecting layer.

7. The wavelength converter according to claim 1, wherein:
the adhesive accounts for 40%˜80% of a mass of the light emitting-reflecting layer.

8. The wavelength converter according to claim 7, wherein:
the adhesive accounts for 45%˜65% of the mass of the light emitting-reflecting layer.

9. The wavelength converter according to claim 7, wherein:
the adhesive is a glass medium,
wherein the glass medium is a continuous glass medium, and
the glass medium includes one or more of SiO₂—B₂O₃—RO, SiO₂—TiO₂—Nb₂O₅—R′₂O, and ZnO—P₂O₅, R including one or more of Mg, Ca, Sr, Ba, Na, and K, and R′ including one or more of Li, Na, and K.

10. The wavelength converter according to claim 7, wherein:
the adhesive is a silica gel or a silicone resin.

11. The wavelength converter according to claim 1, further including:
a substrate disposed at one side of the light emitting-reflecting layer,
wherein the substrate is a ceramic substrate, a metal substrate, or a metal-ceramic alloy substrate.

12. The wavelength converter according to claim 11, further including:
a pure reflective layer disposed between the light emitting-reflecting layer and the substrate, wherein the pure reflective layer comprises aluminum oxide, titanium oxide and an adhesive.

13. A fluorescent color wheel comprising a wavelength converter, wherein:
the wavelength converter comprises a light emitting-reflecting layer,
wherein the light emitting-reflecting layer comprises a wavelength converting material, aluminum oxide, titanium oxide and an adhesive, and
the light emitting-reflecting layer has a ring shape or an annual sector shape.

14. A light-emitting device comprising a wavelength converter and an excitation light source, wherein:
the wavelength converter comprises a light emitting-reflecting layer, the light emitting-reflecting layer comprising a wavelength converting material, aluminum oxide, titanium oxide and an adhesive, and
the excitation light source is a solid-state light source.

15. The fluorescent color wheel according to claim 13, wherein:
the wavelength converting material includes a phosphor;
a particle size of the phosphor is larger than a particle size of the titanium oxide and a particle size of the aluminum oxide; and
the phosphor is a YAG: Ce phosphor or a mixture of a green phosphor and a red phosphor.

16. The fluorescent color wheel according to claim 15, wherein:
the particle size of the phosphor is a range of 1 to 50 μm;
the particle size of the aluminum oxide is in a range of 0.05 to 5 μm;
the particle size of the titanium oxide is in a range of 0.05 to 5 μm.

17. The fluorescent color wheel according to claim 13, wherein:
the wavelength converting material accounts for 20%˜60% of a mass of the light emitting-reflecting layer;
the titanium oxide accounts for 0.1%˜5% of the mass of the light emitting-reflecting layer; and
and the aluminum oxide accounts for 0.1%˜5% of the mass of the light emitting-reflecting layer.

18. The light-emitting device according to claim 14, wherein:
the wavelength converting material includes a phosphor;
a particle size of the phosphor is larger than a particle size of the titanium oxide and a particle size of the aluminum oxide; and
the phosphor is a YAG: Ce phosphor or a mixture of a green phosphor and a red phosphor.

19. The light-emitting device according to claim 18, wherein:
the particle size of the phosphor is a range of 1 to 50 μm;
the particle size of the aluminum oxide is in a range of 0.05 to 5 μm;
the particle size of the titanium oxide is in a range of 0.05 to 5 μm.

20. The light-emitting device according to claim 14, wherein:
the wavelength converting material accounts for 20%˜60% of a mass of the light emitting-reflecting layer;
the titanium oxide accounts for 0.1%˜5% of the mass of the light emitting-reflecting layer; and
and the aluminum oxide accounts for 0.1%˜5% of the mass of the light emitting-reflecting layer.
